(19) United States
(12) Patent Application Publication
(10) Pub. No.: US 2026/0122772 A1
(43) Pub. Date: Apr. 30, 2026

(54) INSULATED METAL SUBSTRATE AND METHOD FOR PRODUCING AN INSULATED METAL SUBSTRATE

(71) Applicant: Hitachi Energy Ltd, Zürich (CH)

(72) Inventors: Lluis SANTOLARIA, Olten (CH); David GUILLON, Vorderthal (CH); Dominik TRUESSEL, Bremgarten (CH); Georg SIROKY, Olten (CH)

(21) Appl. No.: 19/165,026

(22) PCT Filed: Mar. 1, 2024
(86) PCT No.: PCT/EP2024/055448

§ 371 Date: Sep. 12, 2025

(30) Foreign Application Priority Data
Mar. 16, 2023 (EP) 23162305.9

(51) Int. Cl. H05K 1/02; H05K 3/22; H10W 70/04; H10W 70/40

(52) U.S. Cl. CPC H05K 1/0271; H05K 3/22; H10W 70/047; H10W 70/438; H10W 70/479; H05K 2201/2009; H05K 2201/2018; H05K 2203/04

(57) ABSTRACT

An insulated metal substrate (1) for a power semiconductor device is specified, comprising —a metal base (2), —a dielectric layer (3) arranged on the metal base (2), —an electrically conductive layer (4) arranged on the dielectric layer (3), and —a reinforcement structure (5), wherein —the reinforcement structure (5) is arranged in a peripheral region of the insulated metal substrate (1) at least partially surrounding a central region of the insulated metal substrate (1). Furthermore, a method for producing an insulated metal substrate is specified.

The present disclosure relates to an insulated metal substrate for a power semiconductor device and a method for producing an insulated metal substrate.

Embodiments of the disclosure relate to an insulated metal substrate, which is particularly reliable and mechanically stable. A further embodiment of the disclosure relate to a method for producing such an insulated metal substrate.

This is achieved by the subject-matter of the independent claims. Further embodiments are evident from the dependent claims in the following description.

An insulated metal substrate for a power semiconductor device is described. The term “power” here and in the following, for example, refers to power semiconductor devices, power semiconductor modules and/or power semiconductor chips adapted for processing voltages and currents of more than 100 V and/or more than 10 A, exemplary voltages up to 10 kV and currents of amperes up to 5000 A.

According to an embodiment, the insulated metal substrate comprises a metal base. The metal base has a main extension plane extending in lateral directions. The metal base has a back surface and a top surface opposite the back surface. The back surface and the top surface are connected by at least one side surface. The back surface and the top surface both extend, exemplarily, in lateral directions and the at least one side surface extends in vertical direction being perpendicular to the lateral directions. The metal base is formed, in particular, as a plate.

The metal base has a height, for example, in vertical direction of at least 0.5 mm and at most 10 mm, in particular at least 1 mm and at most 2 mm. Exemplarily, the metal base comprises or consists of an electrically conductive material. The metal base comprises or consists in particular of a metal alloy or a metal, such as aluminum and/or copper.

According to the embodiment, the insulated metal substrate comprises a dielectric layer arranged on the metal base. The dielectric layer extends in particular in lateral directions. The dielectric layer has a back surface and a top surface both extending in lateral directions, for example.

For example, the dielectric layer, in particular the back surface of the dielectric layer, is directly arranged on the metal base, in particular the top surface of the metal base. In particular, the dielectric layer is arranged at a first side of the insulated metal substrate. The dielectric layer covers the top surface of the metal base, for example, by at least 80% or 90%. Exemplarily, the dielectric layer completely covers the top layer of the metal base.

The dielectric layer has, for example, a height in vertical direction of at least 50 μm and at most 500 μm, in particular at least 100 μm and at most 200 μm. Exemplarily, the dielectric layer comprises or consists of an electrically insulating material.

According to the embodiment, the insulated metal substrate comprises an electrically conductive layer arranged on the dielectric layer. The electrically conductive layer extends in particular in lateral directions. The electrically conductive layer has a back surface and a top surface both extending in lateral directions, for example.

For example, the electrically conductive layer, in particular the back surface of the electrically conductive layer, is directly arranged on the dielectric layer, in particular the top surface of the dielectric layer. In particular, the electrically conductive layer is arranged at the first side of the insulated metal substrate. The electrically conductive layer covers the top surface of the dielectric layer, for example, by at least 50% or 70% and/or at most 95% or 90%. In particular, the dielectric layer, in particular the top surface of the dielectric layer, is regionally free of the electrically conductive layer.

The electrically conductive layer has, for example, a height in vertical direction of at least 0.1 mm and at most 2.5 mm, in particular at least 0.5 mm and at most 1.0 mm. Exemplarily, the electrically conductive layer comprises or consists of an electrically conductive material. The electrically conductive layer comprises or consists in particular of a metal alloy or a metal, such as aluminum and/or copper.

For example, the metal base, the dielectric layer and the electrically conductive layer are arranged stacked above one another in a stacking direction being the vertical direction perpendicular to the lateral directions.

According to the embodiment, the insulated metal substrate comprises a reinforcement structure. The reinforcement structure has a main extension plane extending in lateral directions. The reinforcement structure has a back surface and a top surface opposite the back surface. The back surface and the top surface are connected by at least two side surfaces, an inner side surface and an outer side surface. The back surface and the top surface both extend, exemplarily, in lateral directions and the at least two side surfaces each extends in vertical direction.

In particular, the reinforcement structure is arranged at the first side of the insulated metal substrate. This is that the reinforcement structure layer faces the top surface of the metal base.

The reinforcement structure has, for example, a height in vertical direction of at least 0.5 mm and at most 8 mm or at most 5 mm. Exemplarily, the reinforcement structure comprises or consists of an electrically conductive material, such as a metal or a metal alloy.

According to the embodiment of the insulated metal substrate, the reinforcement structure is arranged in a peripheral region of the insulated metal substrate at least partially surrounding a central region of the insulated metal substrate.

For example, the inner side surface of the reinforcement structure faces the central region and the outer side surface of the reinforcement structure faces away from the central region. The central region is located at a center of the insulated metal substrate and extends in lateral directions in direction to edges of the insulated metal substrate. The peripheral region extends in lateral directions along the edges of the insulated metal substrate delimiting the central region.

The peripheral region completely surrounds the central region in lateral directions. The reinforcement structure is arranged at least regionally or completely in the peripheral region. For example, the reinforcement structure surrounds the central region in a frame-like manner. “Frame-like” is to be understood as non-limiting with respect to the shape of the reinforcement structure.

Exemplarily, the reinforcement structure is provided connected to the metal base, the dielectric layer and the electrical conductive layer in a mechanically stable manner. This is that the reinforcement structure provides a mechanically stable support for the metal base, the dielectric layer and the electrical conductive layer, thus, reducing or preventing a concave bending of the insulated metal substrate. In particular, a convex bending of the back surface of the insulated metal substrate is achieved. Here and in the following, a concave bending means that the insulated metal substrate is bent, in particular in the central region, in direction to the top surfaces. In other words, a concave bending means that the back surface of the metal base is bent, in particular in the central region, in direction to the electrical conductive layer.

According to the embodiment of the insulated metal substrate, the reinforcement structure does not protrude beyond the metal base in lateral directions. For example, the reinforcement structure does not protrude beyond the dielectric layer and/or the electrical conductive layer in lateral directions. Exemplarily, the outer side surface of the reinforcement structure terminates flush with an outer side surface of the metal base, an outer side surface of the dielectric layer and/or an outer side surface of the electrical conductive layer. In particular, the outer side surface of the reinforcement structure is within a common pane with the outer side surface of the metal base, the outer side surface o the dielectric layer and/or the outer side surface of the electrical conductive layer.

For example, the metal base, the dielectric layer and the electrical conductive layer are a layer stack, which might undergo the bending, in particular the concave bending, during an assembly process, where the layer stack is exposed to heat including phases of heating-up and cooling-down. In particular, the concave bending of the back surface of a metal base of a conventional insulated metal substrate causes several disadvantages when using no reinforcement structure. Such disadvantages are, e.g. an improper thermal interface of the metal base with a heat sink or cracks in the dielectric layer.

In summary, an insulated metal substrate for a power semiconductor device having a reinforcement structure can provide, inter alia, the following advantages. The prevention or at least reduction of the concave bending makes the comparably cost-effective technology of insulated metal substrates usable for large power modules and power modules for higher voltage classes. The reinforcement structure being mechanically rigid can further provide a reduced risk of an isolation breakdown due to cracks in the dielectric layer, caused by stress due to strong bending. Further, such an insulated metal substrate has a reduced concave bending or even a convex bending of the metal base, which is advantageous for a thermal interface between a power module and a cooler. Additionally, such an insulated metal substrate has a reduced long-term increase of a thermal resistance and consequently an increased life-time. Additionally, a reduced bending behaviour due to thermal cycles during operation of the power semiconductor device is achieved, which also improves a long-term behaviour of a thermal interface and consequently a reliability, e.g. less pump-out of thermal interface material. Moreover, such insulated metal substrates have a reduced weight compared to standard setup, where substrates are soldered on a baseplate. Such an insulated metal substrate requires also a reduced number of process steps in the assembly process.

Such insulated metal substrate can be in particular used in low voltage industrial and automotive products.

According to a further embodiment of the insulated metal substrate, the dielectric layer is an electrically insulating resin layer.

The insulated metal substrate exemplarily comprises or consists of an epoxy resin comprising an inorganic filler. The inorganic filler comprises or consists of a ceramic material like aluminium nitride (AN), silicon nitride (Si3N4), boron nitride (BN), and/or aluminium oxide (Al2O3).

According to a further embodiment of the insulated metal substrate, the electrically conductive layer comprises a circuit metallization. The circuit metallization comprises, for example, a plurality of parts. At least some of the parts are arranged spaced apart from one another in lateral directions. This is that at least some of the parts are electrically insulated from one another.

The circuit metallization is configured, for example, to be connected to at least one power semiconductor device in the central region.

According to a further embodiment of the insulated metal substrate, the reinforcement structure has a height, which is equal or larger than a height of the electrically conductive layer. The height of the reinforcement structure is an extent of the reinforcement layer from the back surface to the top surface in vertical direction. Further, the height of the electrically conductive layer is an extent of the electrically conductive layer from the back surface to the top surface in vertical direction. In particular, all the parts have the same height.

Exemplarily, the top surface of the reinforcement structure protrudes above the top surface of the electrically conductive layer in vertical direction facing away from the metal base.

For example, the height of the reinforcement structure is at most 7.5 mm or 4.5 mm higher than the height of the electrically conductive layer.

Alternatively, the reinforcement structure has a height, which is smaller than a height of the electrically conductive layer. The height of the reinforcement structure is determined in view of the physical properties of the material used for the reinforcement structure. The physical properties can be Young Modulus, thermal expansion coefficient and such other physical properties relating to softness or hardness of the material and its behavior with temperature change. The higher the value of Young modulus, the smaller can be the height or thickness required for the reinforcement structure, determined for materials with similar thermal expansion coefficients (constant coefficient of thermal expansion, CTE values).

According to a further embodiment of the insulated metal substrate, the reinforcement structure is formed continuously. In particular, the reinforcement structure completely encloses the central region in lateral directions. This is that the reinforcement structure is formed continuously connected. Exemplarily, the reinforcement structure is formed as one piece.

Alternatively, the reinforcement structure being formed continuously comprises at least two portions, which are formed of a different material. Exemplarily, the portions are connected to one another.

According to a further embodiment of the insulated metal substrate, the reinforcement structure is formed discontinuously. This is that the reinforcement structure is formed not continuously connected. In particular, the reinforcement structure comprises at least two sections. The sections are exemplarily spaced apart from one another in lateral directions. Exemplarily, the reinforcement structure is formed as separate pieces, i.e. segments.

The segments can be all formed of the same material. Alternatively, at least two of the segments are formed of a different material.

According to a further embodiment of the insulated metal substrate, at least one of a height of the reinforcement structure and a width of the reinforcement structure is uniform. The width of the reinforcement structure is a minimal extent of the reinforcement layer from the inner side surface to the outer side surface in lateral directions.

Exemplarily, the height of the reinforcement structure is the same for every region in the peripheral region. For example, the width of the reinforcement structure is the same for every region in the peripheral region, except corner regions of the insulated metal substrate. For example, at corner regions of the reinforcement structure, a width is increased in comparison to regions where the reinforcement structure extends straight.

For example, the width of the reinforcement structure is at least 1 mm and at most 20 mm or at most 10 mm.

According to a further embodiment of the insulated metal substrate, at least one of a height of the reinforcement structure and a width of the reinforcement structure is non-uniform. Exemplarily, the height of the reinforcement structure is different for at least two regions in the peripheral region. For example, the width of the reinforcement structure is different for at least two regions in the peripheral region.

According to a further embodiment of the insulated metal substrate, the reinforcement structure comprises at least one additional reinforcement structure. For example, the additional reinforcement structure is arranged at the first side of the insulated metal substrate. This is that the additional reinforcement structure layer faces the top surface of the metal base.

The additional reinforcement structure has, for example, a height in vertical direction of at least 0.5 mm and at most 8 mm or at most 5 mm. Exemplarily, the additional reinforcement structure comprises or consists of an electrically conductive material, such as a metal or a metal alloy. The additional reinforcement structure can be formed of the same material than the reinforcement structure or of a different material.

Advantageously, the additional reinforcement structure further increases the mechanically stable support for the metal base, the dielectric layer and the electrical conductive layer, thus, reducing the concave bending of the insulated metal substrate.

According to a further embodiment of the insulated metal substrate, the at least one additional reinforcement structure extends in the central region. In particular, the additional reinforcement structure is arranged in the central region. For example, the additional reinforcement structure extends from the peripheral region in lateral directions in the central region.

According to a further embodiment of the insulated metal substrate, the at least one additional reinforcement structure is formed integrally with the reinforcement structure. This is that the additional reinforcement structure can be formed as one piece with the reinforcement structure. For example, the additional reinforcement structure is continuously connected with the additional reinforcement structure.

Alternatively, the additional reinforcement structure and the reinforcement structure are formed of a different material and which are adhered to one another.

According to a further embodiment of the insulated metal substrate, the at least one additional reinforcement structure is spaced apart from the reinforcement structure. This is that the additional reinforcement structure can be formed as a separate piece with the reinforcement structure. For example, the additional reinforcement structure is not continuously connected with the additional reinforcement structure.

The additional reinforcement structure advantageously improves the mechanical stability of the insulated metal substrate. Advantageously, for an improved suppression or at least reduction of the concave bending in the central region of the insulated metal substrate, the additional reinforcement structure is arranged in the central region or placed on locations, where a strongest bending would occur.

According to a further embodiment of the insulated metal substrate, the at least one additional reinforcement structure is configured to divide the central region in at least two segments. For example, the additional reinforcement structure completely extends between opposite side surfaces, i.e. opposite inner side surfaces, of the reinforcement structure.

According to a further embodiment of the insulated metal substrate, the reinforcement structure comprises a metal, a polymer material and/or an inorganic material.

Exemplarily, the height and/or a width of the reinforcement structure and/or the material of the reinforcement structure is predetermined dependent on the bending of the metal base, the dielectric layer and the electrically conductive layer in an assembly process without the reinforcement structure. For example, the layer stack is comparatively flat, i.e. has no bending, at an initial temperature T1 during a joining process, exemplarily with power semiconductor devices. However, the layer stack has, for example, the concave bending during cooling down to a further temperature, being smaller than the initial temperature, due to a “mechanical dominance” of the metal base against the dielectric layer and the electrically conductive layer. This is that the material of the reinforcement structure is predetermined such that the reinforcement structure has a smaller thermal expansion coefficient than the metal base, whose comparably large expansion coefficient results in strong bending during cooling down if no reinforcement structure is available. The thickness of the reinforcement structure is, for example, predetermined by a Young modulus referring to a rigidness of the material of the reinforcement structure. Additionally, a reduced bending behaviour due to thermal cycles during operation of the power semiconductor device is considered, which would also improve long-term behaviour of a thermal interface and consequently a reliability.

At least a flat back surface of the metal base is, inter alia, achieved by the following formula:

$${d}_{metal\_base} {ε}_{metal\_base} {λ}_{metal\_base} + {d}_{dielectric\_layer} {ε}_{dielectric\_layer} {λ}_{dielectric\_layer} = {d}_{reinforcment\_structure} {ε}_{reinforcment\_structure} {λ}_{reinforcment\_structure}$$

Wherein d is the corresponding height, ε is the corresponding Young modulus, λ is the corresponding thermal expansion coefficient.

For example, dependent on the height, the Young modulus and the thermal expansion coefficient of the reinforcement structure with respect to the metal base, the dielectric layer and/or the electrically conductive layer, a defined convex bending of the back surface of the metal base is advantageously achievable or at least a concave bending is reduced or suppressed. With such a convex bending, cooling efficiency can be advantageously increased.

According to a further embodiment of the insulated metal substrate, the reinforcement structure is arranged on the metal base. For example, in the peripheral region, the metal base is free of the dielectric layer and the electrically conductive layer. The reinforcement structure is in the peripheral region directly and immediately in contact with the metal base.

According to a further embodiment of the insulated metal substrate, the reinforcement structure is arranged on the dielectric layer. For example, the top surface of the metal base is completely covered with the dielectric layer and the top surface of the dielectric layer is free of the electrically conductive layer in the peripheral region. The reinforcement structure is in the peripheral region directly and immediately in contact with the dielectric layer.

Exemplary, the additional reinforcement structure is arranged on the dielectric layer. This is that the top surface of the dielectric layer is free of the electrically conductive layer in the central region, where the additional reinforcement structure is arranged.

According to a further embodiment of the insulated metal substrate, the reinforcement structure is arranged on the electrically conductive layer. For example, the top surface of the metal base is completely covered with the dielectric layer. The electrically conductive layer is arranged in the peripheral region on the dielectric layer. This is that at least one of the parts are arranged in the peripheral region. The reinforcement structure is in the peripheral region directly and immediately in contact with the electrically conductive layer.

Exemplary, the additional reinforcement structure is arranged on the electrically conductive layer. This is that the additional reinforcement structure is arranged, for example, in the central region on one of at least one of the parts.

According to a further embodiment of the insulated metal substrate, an electric potential of the reinforcement structure is grounded. Exemplary, the reinforcement structure and/or the additional reinforcement structure are electrically conductive connected to the electrical conductive layer or the metal base.

Alternatively, the electric potential of the reinforcement structure is floating. This is, for example, that the reinforcement structure does not have any electrically conductive connection to the electrical conductive layer or the metal base.

According to a further embodiment of the insulated metal substrate, the reinforcement structure is grounded by at least one screw and/or the reinforcement structure is grounded by at least one bonding wire. For example, the reinforcement structure is electrically conductively connected to the metal base via the screw and/or the bonding wire or with a part of the circuit metallization. Alternatively, the reinforcement structure is directly electrically conductively connected to a base material of the metal base. In particular, the metal base is connected to the ground of the insulated metal substrate.

Exemplarily, the reinforcement structure comprises at least one opening, completely penetrating the reinforcement structure in vertical direction. The opening is configured to receive the screw or a bolt, with which the reinforcement structure can be connected to the metal base and additionally with which the insulated metal substrate or a complete power module can be connected to a cooler or heat sink. Furthermore, the dielectric layer and/or the electrically conductive connection comprises at least one further opening. The further opening completely overlaps with the opening in lateral directions, in particular congruently.

Furthermore, a method for producing an insulated metal substrate is described here, with which an insulated metal substrate as described herein above can be produced or is produced. Therefore, the features in connection with the insulated metal substrate are disclosed also in connection with the method and vice versa.

According to an embodiment of the method, a metal base is provided.

According to an embodiment of the method, a dielectric layer is provided, which is arranged on the metal base.

According to an embodiment of the method, an electrically conductive layer is provided, which is arranged on the dielectric layer. Exemplarily, a material of the conductive layer is applied on the dielectric layer. The material of the conductive layer completely covers the top surface of the dielectric layer. For example, after the application of the material of the conductive layer, the material of the conductive layer is structured to the electrically conductive layer. The structuring is achieved, for example, with a chemical etching process and/or a physical etching process.

Alternatively, the metal base and the parts of the circuit metallization are provided and the dielectric layer is molded.

According to an embodiment of the method, a reinforcement structure is provided, wherein the reinforcement structure is provided in a peripheral region of the insulated metal substrate.

Furthermore, such a method for an insulated metal substrate has advantageously a reduction of process steps in an assembly process, as e.g. no process for joining of substrates to a baseplate is needed.

According to an embodiment of the method, the reinforcement structure is applied to at least one of the metal base, the dielectric layer and the electrically conductive layer. In particular, the reinforcement structure is prefabricated and applied to at least one of the metal base, the dielectric layer and the electrically conductive layer.

According to an embodiment of the method, the reinforcement structure is applied by at least one of the following processes: lamination, gluing, soldering, sintering, brazing, gluing, screwing.

According to an embodiment of the method, the reinforcement structure is produced from a base material of the metal base. Exemplarily, the base material of the metal base is provided. After the provision of the base material of the metal base, the base material is structured to the metal base and the reinforcement structure from an integral structure, i.e. the base material. The structuring is achieved, for example, with an etching process or a grinding process.

The accompanying Figures are included to provide a further understanding. In the Figures, elements of the same structure and/or functionality may be referenced by the same reference signs. It is to be understood that the embodiments shown in the Figures are illustrative representations and are not necessarily drawn to scale.

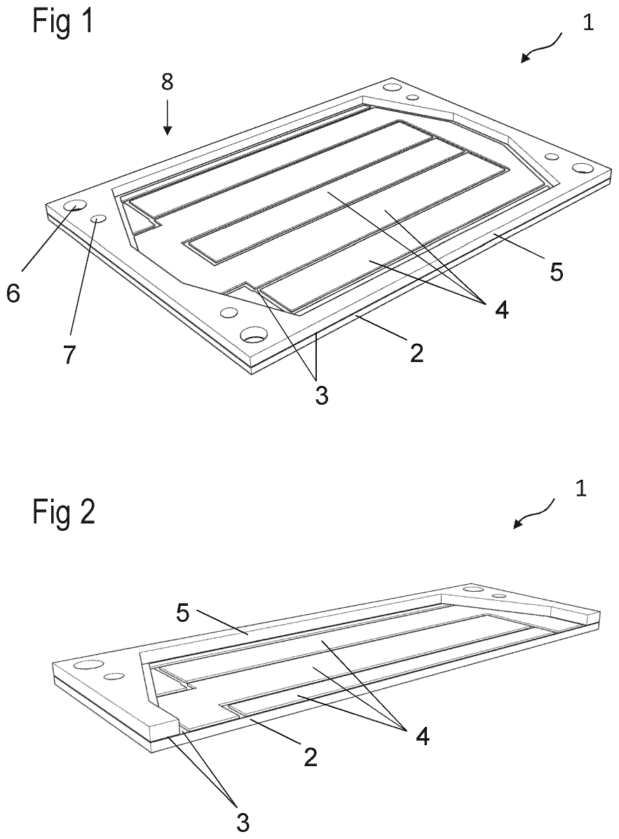

FIG. 1 is a schematic three dimensional view of an insulated metal substrate according to an exemplary embodiment,

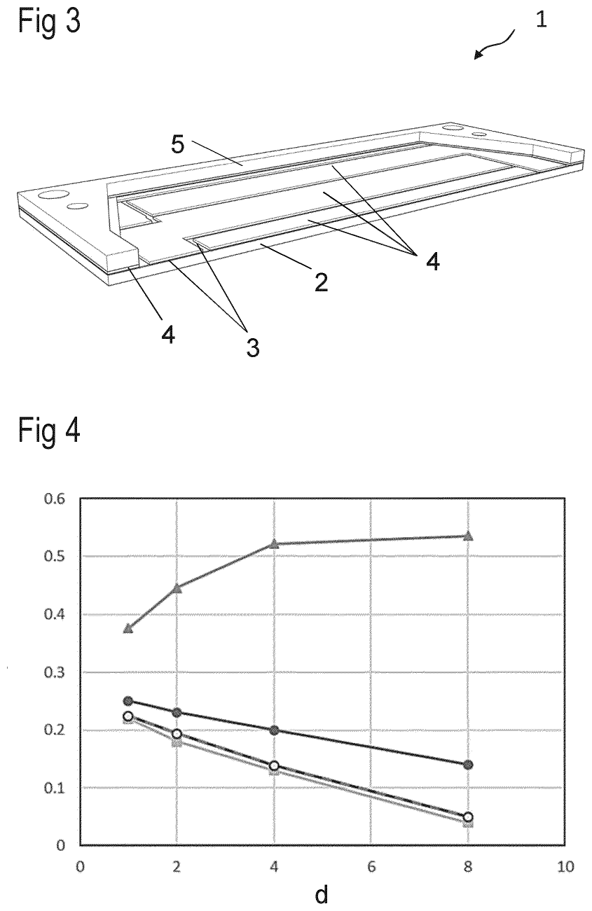

FIGS. 2 and 3 each is a schematic three dimensional cross-sectional view of an insulated metal substrate each according to an exemplary embodiment, and

FIG. 4 is a simulation of a vertical displacement of an insulated metal substrate according to an exemplary embodiment dependent on a height of the reinforcement structure for different materials of the reinforcement structure.

The insulated metal substrate 1 according to the exemplary embodiment of FIG. 1 comprises a metal base 2, a dielectric layer 3 and an electrically conductive layer 4 arranged stacked above one another in a stacking direction being a vertical direction.

A top surface of the metal base 2 is completely covered with the dielectric layer 3. The dielectric layer 3 is arranged on the top surface at a first side of the insulated metal substrate 1. Furthermore, the dielectric layer 3 is an electrically insulating resin layer being formed electrically insulating.

The electrically conductive layer 4 is arranged on a top surface of the dielectric layer 3 at the first side 8. Furthermore, the electrically conductive layer 4 comprises a circuit metallization being formed electrically conductive. This is that the electrically conductive layer 4 comprises a plurality of parts, wherein at least some of the parts are spaced apart from one another in lateral directions, which extend perpendicular to the vertical direction.

The metal base 2, the dielectric layer 3 and the electrically conductive layer 4 are formed, in particular, as a layer stack. The metal base 2, the dielectric layer 3 and the electrically conductive layer 4 each have a height. The height of the metal base 2 is formed uniform over its extension. The height of the dielectric layer 3 is formed uniform over its extension. The height of the electrically conductive layer 4, in particular the parts, is formed uniform over its extension. “Uniform” means that each of the heights can vary slightly, i.e. at least by at most 5%, due to production tolerances. The same is applicable with respect to a uniform width.

The insulated metal substrate 1 has in addition a reinforcement structure 5, which is arranged in a peripheral region of the insulated metal substrate 1 surrounding a central region of the insulated metal substrate 1. In particular, the reinforcement structure 5 is arranged on the top surface of the dielectric layer 3 at the first side 8. The reinforcement structure 5 is in direct contact to the dielectric layer 3.

In particular, the metal base 2 and the dielectric layer 3 both have a mainly quadrangular shape. Mainly means that the quadrangular shape has chamfered corners or rounded corners. Further, an outer side surface of the reinforcement structure 5 has a quadrangular contour and an inner side surface being opposite the outer side surface and facing the central region has an octangular contour. A distance in lateral directions of the outer side surface to the inner side surface defines a width of the reinforcement structure 5. The width of the reinforcement structure 5 increases in direction to corners of the quadrangular contour.

The top surface of the dielectric layer 3 is free of the electrically conductive layer 4 in the peripheral region, in which the reinforcement structure 5 is arranged. This is that the electrically conductive layer 4 is solely arranged in the central region, which is completely surrounded in lateral directions by the reinforcement structure 5.

The reinforcement structure 5 has a height in vertical direction, which is larger than the height of the electrically conductive layer 4. In particular, the height of the reinforcement structure 5 is at most 4.5 mm higher than the height of the electrically conductive layer 4.

In each region of each of the corners of the quadrangular contour, an opening 6 is arranged. Each of the openings 6 is configured to receive a screw, with which the reinforcement structure 5 is grounded to the metal base 2.

Further, in each of the regions of each of the corners of the quadrangular contour, a recess 7 is arranged spaced apart in lateral directions from the opening 6. Each of the recesses 7 has a smaller circumference than the openings 6. Exemplarily, the recesses 7 are configured to receive adjustment pins of a part of a power semiconductor component or a part of a power semiconductor module configured to be mounted on the insulated metal substrate 1.

The exemplary embodiment of FIG. 2 relates to the exemplary embodiment of FIG. 1. The reinforcement structure 5 is arranged directly on the dielectric layer 3 in the peripheral region completely surrounding the central region.

In contrast to the exemplary embodiment of FIG. 2, the reinforcement structure 5 is arranged on the electrically conductive layer 4 in the exemplary embodiment of FIG. 3. One of the parts of the electrically conductive layer 4 is arranged in the peripheral region. The one of the parts in the peripheral region is spaced apart from the other parts of the electrically conductive layer 4 in the central region in lateral directions.

Exemplarily, finite element simulations show an impact of a height of the reinforcement structure 5 and a material of the reinforcement structure 5 on a bending of the insulated metal substrate 1 due to cooling down by 100 K, as exemplarily shown in FIG. 4.

The insulated metal substrate 1 used for an exemplary simulation has a metal base 2 being formed of copper. For example, the reinforcement structure 5 of the insulated metal substrate 1 used for the exemplary simulation is formed of aluminium. At an initial temperature T1, the insulated metal substrate 1, in particular the metal base 2, is assumed to be flat and stress-free.

Exemplarily the exemplary simulation is performed for different heights of the reinforcement structure 5, i.e. being 2 mm, 4 mm, and 8 mm. A vertical difference, corresponding to an unwanted concave bending of the back surface of the metal base 2, after cooling down by 100 K is defined by a vertical difference between a highest and a lowest point of the back surface of the metal base 2 in vertical direction. The simulation results in a vertical difference of 0.22 mm for a height of 1 mm, 0.18 mm for 2 mm, 0.13 mm for 4 mm, and 0.04 mm for 8 mm.

This is that the vertical differences, i.e. the bending of the insulated metal substrate 1 is dependent on the height of the reinforcement structure 5.

The diagram according to FIG. 4 shows simulation results similar to the exemplary simulation and an impact of different materials of the reinforcement structure 5, in particular with respect to Young modulus, a thermal expansion coefficient, and of different heights of the reinforcement structure 5. Vertical differences, z, are depicted on the y-axis in mm and heights of the reinforcement structure 5, d, are depicted on the x-axis of the diagram.

The simulation points being characterised by triangles correspond to a reinforcement structure 5 comprising iron-nickel alloy. The simulation points being characterised by filled circles correspond to a reinforcement structure 5 comprising copper. The simulation points being characterised by squares correspond to a reinforcement structure 5 comprising aluminium. The simulation points being characterised by open circles correspond to a reinforcement structure 5 comprising a magnesium alloy or stainless steel.

A strongest reduction in bending is achieved, if the reinforcement structure 5 comprises aluminium, magnesium alloy, or stainless steel.

A weaker reduction in bending can be achieved, if the reinforcement structure 5 comprises copper.

If the reinforcement structure 5 comprises the iron-nickel alloy, the opposite effect of a stronger bending is achieved, which increases with increasing the height of the reinforcement structure 5. In particular, the iron-nickel alloy has a smaller thermal expansion coefficient than the metal base 2, whereas all other materials of the reinforcement structure 5 have a higher thermal expansion coefficient than the metal base 2.

### REFERENCE SIGNS

1 insulated metal substrate
2 metal base
3 dielectric layer
4 electrically conductive layer
5 reinforcement structure
6 opening
7 recess
8 first side

1. An insulated metal substrate for a power semiconductor device comprising:
a metal base;
a dielectric layer arranged on the metal base;
an electrically conductive layer arranged on the dielectric layer; and
a reinforcement structure, wherein
the reinforcement structure is arranged in a peripheral region of the insulated metal substrate at least partially surrounds a central region of the insulated metal substrate,
the reinforcement structure does not protrude beyond the metal base in lateral directions, and
the reinforcement structure consists of a metal.

2. The insulated metal substrate according to claim 1, wherein at least one of
the dielectric layer is an electrically insulating resin layer, and the electrically conductive layer comprises a circuit metallization.

3. The insulated metal substrate according to claim 1, wherein the reinforcement structure has a height, which is equal or larger than a height of the electrically conductive layer.

4. The insulated metal substrate according to claim 1, wherein the reinforcement structure is formed continuously.

5. The insulated metal substrate according to claim 1, wherein the reinforcement structure is formed discontinuously.

6. The insulated metal substrate according to claim 1, wherein at least one of a height of the reinforcement structure and a width of the reinforcement structure is uniform, and/or at least one of a height of the reinforcement structure and a width of the reinforcement structure is non-uniform.

7. The insulated metal substrate according to claim 1, wherein the reinforcement structure comprises at least one additional reinforcement structure, and the at least one additional reinforcement structure extends in the central region.

8. The insulated metal substrate according to claim 7, wherein the at least one additional reinforcement structure is formed integrally with the reinforcement structure, or the at least one additional reinforcement structure is spaced apart from the reinforcement structure.

9. The insulated metal substrate according to claim claim 7, wherein the at least one additional reinforcement structure is configured to divide the central region in at least two segments.

10. (canceled)

11. The insulated metal substrate according to claim 1, wherein at least one of;
the reinforcement structure is arranged on the metal base,
the reinforcement structure is arranged on the dielectric layer or
the reinforcement structure is arranged on the electrically conductive layer.

12. The insulated metal substrate according to claim 1, wherein
an electric potential of the reinforcement structure is grounded, and
the reinforcement structure is grounded by at least one screw and/or the reinforcement structure is grounded by at least one bonding wire.

13. A method for producing an insulated metal substrate for a power semiconductor device, the method comprising:
providing a metal base;
providing a dielectric layer, which is arranged on the metal base;
providing an electrically conductive layer, which is arranged on the dielectric layer; and
providing a reinforcement structure, wherein
the reinforcement structure is provided in a peripheral region of the insulated metal substrate,
the reinforcement structure does not protrude beyond the metal base in lateral directions, and
the reinforcement structure consists of a metal.

14. The method according to claim 13, wherein the reinforcement structure is applied to at least one of the metal base, the dielectric layer and the electrically conductive layer, and the reinforcement structure is applied by at least one of the following processes: lamination, gluing, soldering, sintering, brazing, or screwing.

15. The method according to claim 13, wherein the reinforcement structure is produced from a base material of the metal base.
